(19) United States
(12) Patent Application Publication
(10) Pub. No.: US 2010/0291483 A1
(43) Pub. Date: Nov. 18, 2010

(54) RESIST UNDERLAYER FILM FORMING COMPOSITION CONTAINING BRANCHED POLYHYDROXYSTYRENE

(75) Inventors: Takahiro Hamada, Toyama-shi (JP); Noriaki Fujitani, Toyama-shi (JP)

Correspondence Address: OLIFF & BERRIDGE, PLC, P.O. BOX 320850, ALEXANDRIA, VA, 22320-4850, US

(73) Assignee: NISSAN CHEMICAL INDUSTRIES, LTD., Tokyo (JP)

(21) Appl. No.: 12/676,720

(22) PCT Filed: Sep. 18, 2008
(86) PCT No.: PCT/JP2008/066856

§ 371 Date: Jul. 29, 2010

(30) Foreign Application Priority Data
Sep. 20, 2007 (JP) 2007-243602

(51) Int. Cl. G03F 7/004; G03F 7/20

(52) U.S. Cl. 430/282.1; 430/322; 430/315

(57) ABSTRACT

There is provided a resist underlayer film which does not intermix with a photoresist coated and formed as the overlying layer and which dissolves in an alkaline developer and can be developed and removed at the same time as the photoresist; and a resist underlayer film-forming composition for forming such a resist underlayer film. A resist underlayer film-forming composition for use in a lithographic process for manufacturing a semiconductor device, containing: (A) a branched polyhydroxystyrene in which an ethylene repeating unit on a polyhydroxystyrene moiety is bonded to a benzene ring on a different polyhydroxystyrene moiety; (B) a compound having at least two vinyl ether groups; and (C) a photoacid generator.

### TECHNICAL FIELD

The present invention relates to a resist underlayer film for use in a lithographic process for manufacturing semiconductor devices, and also relates to a process for manufacturing semiconductor devices using such a resist underlayer film.

### BACKGROUND ART

The manufacture of semiconductor devices entails carrying out micro fabrication by means of lithography using a photoresist. Microfabrication is a process wherein a thin film of photoresist is formed on a semiconductor substrate such as a silicon wafer, then is irradiated with actinic light such as ultraviolet light through an overlying mask on which a device pattern has been written, and developed to form a photoresist pattern. With the photoresist pattern serving as a protective layer, the substrate is etched so as to form very fine topographic features corresponding to the pattern. In recent years, with the increasing level of device integration, there has been a trend toward shorter wavelengths in the exposure light used—from KrF excimer lasers (wavelength, 248 nm) to ArF excimer lasers (wavelength, 193 nm). However, one problem associated with such photolithographic operations is a decline in the dimensional accuracy of photoresist patterning, both because of the effect of standing waves resulting from the reflection of exposure light from the substrate and because of the effect of the irregular reflection of exposure light arising from the unevenness of the substrate. To overcome this problem, methods in which a bottom anti-reflective coating (BARC) is provided between the photoresist and the substrate are being widely investigated.

Such anti-reflective coatings are often formed using a thermally crosslinkable composition in order to prevent intermixing with the photoresist applied thereon. As a result, the anti-reflective coating that has been formed ends up being insoluble in the alkaline developer used to develop the photoresist. For this reason, removal of the anti-reflective coating prior to working the semiconductor substrate requires that dry etching be carried out (see, for example, Patent Document 1).

However, when dry etching is used to remove the anti-reflective coating, such dry etching at the same time removes also the photoresist. It is thus difficult to ensure that the photoresist film thickness required to work the substrate is achieved. This is a major challenge particularly in cases where a thin-film photoresist is used for the purpose of enhancing the resolution.

Also, in semiconductor device fabrication, ion implantation is a step in which impurities are introduced into a semiconductor substrate while using a photoresist pattern as the template. In this step, to avoid damaging the surface of the substrate, a dry etching step cannot be carried out in connection with patterning of the photoresist. Therefore, in photoresist patterning for the ion implantation step, it has not been possible to use an anti-reflective coating that requires removal by dry etching as the photoresist underlayer. Up until now, because the photoresist patterns used as templates in the ion implantation step have had large pattern linewidths, the influence of standing waves due to reflection of the exposure light from the substrate and the influence of irregular reflection of exposure light due to unevenness of the substrate have been small. Therefore, problems due to reflection have been resolved by using a dye-containing photoresist or using an anti-reflective coating as the photoresist overlayer. However, with the recent trend toward smaller geometries, there has begun to be a need for very fine patterns even among photoresists used in the ion implantation step. This in turn has created a need for an anti-reflective coating as the photoresist underlayer.

As a result, there has existed a desire for the development of a bottom anti-reflective coating which will dissolve in the alkaline developer used for developing the photoresist and can be developed and removed at the same time as the photoresist. Although researches on anti-reflective coatings which can be developed and removed at the same time as the photoresist have hitherto been carried out (see, for example, Patent Document 2, Patent Document 3, Patent Document 4, and Patent Document 5), the coatings arrived at in such researches have left something to be desired in terms of, for example, their applicability to microfabrication, and the shapes of the patterns formed therewith. In addition, the applicant has previously disclosed an anti-reflective coating-forming composition which includes a hydroxystyrene unit-containing polymer as an alkali-soluble compound (Patent Document 6).

Patent Application 1: Specification of U.S. Pat. No. 6,156,479
Patent Application 2: Japanese Patent Application Publication No. JP-A-2004-54286
Patent Application 3: Japanese Patent Application Publication No. JP-A-2005-70154

### Patent Application 4: WO 05/093513

### Patent Application 5: WO 05/111719

### Patent Application 6: WO 05/111724

### DISCLOSURE OF THE INVENTION

### Problems to be Solved by the Invention

The objects of the present invention are to provide a resist underlayer film which is soluble in an alkaline developer, and to provide a composition for forming such a resist underlayer film.

That is, one object of the present invention is to provide a resist underlayer film-forming composition for use in the manufacture of semiconductor devices. A further object is to provide a resist underlayer film which does not intermix with a photoresist coated and formed as the overlying layer and which dissolves in an alkaline developer and can be developed and removed at the same time as the photoresist. A still further object is to provide a resist underlayer film-forming composition for forming such a resist underlayer film.

### Means for Solving the Problems

In a first aspect, the present invention provides a resist underlayer film-forming composition for use in a lithographic process for manufacturing a semiconductor device, the composition containing: (A) a branched polyhydroxystyrene in which an ethylene repeating unit on a polyhydroxystyrene moiety is bonded to a benzene ring on a different polyhydroxystyrene moiety, (B) a compound having at least two vinyl ether groups, and (C) a photoacid generator.

In a second aspect, the present invention provides the resist underlay film-forming composition according to the first aspect, wherein the branched polyhydroxystyrene (A) includes a structure of Formula (1)

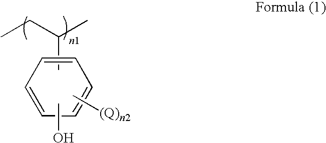

[where Q is a polyhydroxystyrene moiety bonded to a benzene ring, n1 is a number from 1 to 100 representing the number of ethylene repeating units, n2 is an integer from 0 to 4 representing the number of Q substituents bonded to the benzene ring, and Q has Formula (2), (3) or (4)

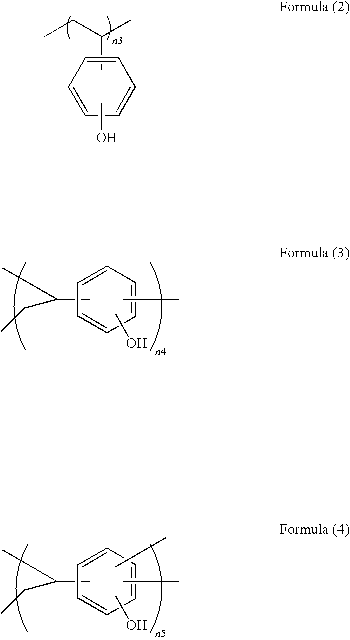

(where n3, n4 and n5 are respectively integers from 1 to 100 which represent the number of repeating units therein) or is a combination thereof] and has a weight average molecular weight of from 1,000 to 100,000.

In a third aspect, the present invention provides the resist underlayer film-forming composition of the second aspect, wherein the branched polyhydroxystyrene (A) has a proportion of the number of moles of repeating units of Formula (1), in which n2 in the formula is 0, ranging from 5 to 30% and a proportion of the number of moles of repeating units of Formula (1), in which n2 in the formula is 1, ranging from 70 to 95% (the sum of the proportions of the number of moles being 100%), and has, with respect to Q, a molar ratio of repeating units of Formula (2) to repeating units of Formula (3) to repeating units of Formula (4) of 1:0.5 to 1.5:0.5 to 1.5.

In a fourth aspect, the present invention provides the resist underlayer film-forming composition according to any one of the first to third aspects, wherein the compound (B) having at least two vinyl ether groups is a compound of Formula (5)

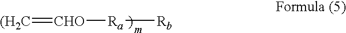

(where Rₐ is a divalent organic group selected from the group consisting of C₁₋₁₀ alkyl, C₆₋₁₈ aryl, C₆₋₂₅ arylalkyl, C₂₋₁₀ alkylcarbonyl, C₂₋₁₀ alkylcarbonyloxy, C₂₋₁₀ alkylcarbonylamino and C₂₋₁₀ aryloxyalkyl; R_{b} is an organic group with a valence of 2 to 4 selected from the group consisting of C₁₋₁₀ alkyl and C₆₋₁₈ aryl; and m is an integer from 2 to 4).

In a fifth aspect, the present invention provides the resist underlayer film-forming composition according to any one of the first to fourth aspects, further including (D) a light-absorbing compound.

In a sixth aspect, the present invention provides the resist underlayer film-forming composition according to any one of the first to fifth aspects, further including (E) an amine.

In a seventh aspect, the present invention provides a method for forming photoresist pattern for use in semiconductor manufacture, which process includes the step of forming a resist underlayer film by coating the resist underlayer film-forming composition of any one of the first to sixth aspects onto a semiconductor substrate and baking the coated composition.

In an eighth aspect, the present invention provides a method for manufacturing semiconductor device which includes the steps of: forming a resist underlayer film on a semiconductor substrate using the resist underlayer film-forming composition according to any one of the first to sixth aspects; forming a resist film on the resist underlayer film; and forming a resist pattern by exposure and development.

In a ninth aspect, the present invention provides the semiconductor device manufacturing process of the eighth aspect, wherein areas that have been exposed exhibit alkali solubility and are removed in use of a developer to form a resist pattern.

### EFFECTS OF THE INVENTION

The resist underlay film-forming compositions in the present invention include (A) a branched polyhydroxystyrene wherein an ethylene repeating unit on a polyhydroxystyrene moiety is bonded to a benzene ring on a different polyhydroxystyrene moiety, (B) a compound having at least two vinyl ether groups and (C) a photoacid generator, and are soluble in a solvent. These resist underlayer film-forming compositions are coated onto a semiconductor substrate, then are baked at a temperature at which the solvent is removed, and thermally crosslinked by subsequent baking.

In addition, a light-absorbing compound (D) and an amine (E) may be included as optional ingredients.

Thermal crosslinking is carried out between the branched polyhydroxystyrene (A) and the compound (B) having at least two vinyl ether groups. Such crosslinking can also be carried out between the branched polyhydroxystyrene (A), the light-absorbing compound (D) and/or amine (E), and the compound (B) having at least two vinyl ether groups.

The light-absorbing compound (D) and the amine (E) preferably have a hydroxyl group.

Acetal bonds or bonds similar thereto form between the branched polyhydroxystyrene (A), a hydroxyl group or carboxyl group on the light-absorbing compound (D) and/or amine (E), and the vinyl ether group-bearing compound (B), giving rise to thermal crosslinking and the formation of a crosslinked polymer. The reaction of the carboxyl group with a vinyl ether group-bearing compound creates a carbon atom-containing bond having one ether oxygen atom and one ester oxygen atom bonded on either side, and the reaction of the hydroxyl group with a vinyl ether group-containing compound creates a carbon atom-containing bond having two ether oxygen atoms bonded on either side. In both the former and the latter cases, these carbon-oxygen bonds are easily cleaved by an acid (the acid generated by the photoacid generator (C) at the time of exposure), and decompose into a carboxyl group and a hydroxyl group.

Therefore, in areas that have been exposed through a photomask, the acetal bonds or bonds similar thereto are cleaved by the acid that has formed as a result of decomposition of the photoacid generator, thereby creating carboxyl groups and hydroxyl groups. As a result, those areas exhibit alkali solubility (solubility in the developer) and are developed.

The bonds that have formed between the branched polyhydroxystyrene (A) and the vinyl ether group-bearing compound (B) are cleaved, creating hydroxyl groups, and likewise exhibiting alkali solubility.

In the present invention, with regard to the acetal bonds or bonds similar thereto, because numerous acetal bonds between the branched polyhydroxystyrene (A), the hydroxyl groups or carboxyl groups of the light-absorbing compound (D) and/or the amine (E), and the compound (B) having at least two vinyl ether groups form within the resist underlayer film, when exposure then development are carried out using a fine pattern, the places where bonds cleave are numerous. Also, because many phenolic hydroxyl groups are regenerated, very fine patterns can be created, enabling an increased resolution to be achieved.

### BEST MODES FOR CARRYING OUT THE INVENTION

A resist underlayer film-forming composition of the present invention for use in a lithographic process for manufacturing semiconductor devices includes (A) a branched polyhydroxystyrene wherein an ethylene repeating unit on a polyhydroxystyrene moiety is bonded to a benzene ring on a different polyhydroxystyrene moiety, (B) a compound having at least two vinyl ether groups, and (C) a photoacid generator, these being dissolved in a solvent. In addition, the composition may also include (D) a light-absorbing compound and (E) an amine, and may further include a surfactant and the like.

The total solids, after excluding the solvent from the resist composition, are from 0.1 to 70 mass %, and preferably from 1 to 60 mass %.

The content of the branched polyhydroxystyrene (A) within the resist underlayer film-forming composition solids is at least 10 mass %, such as from 30 to 99 mass %, from 49 to 90 mass %, or even from 59 to 80 mass %.

The branched polyhydroxystyrene (A) used in the present invention has a weight-average molecular weight of from 100 to 1,000,000, and preferably from 1,000 to 100,000.

In Formula (1), Q is a polyhydroxystyrene moiety bonded to a benzene ring, n1 is a number from 1 to 100 representing the number of ethylene repeating units, and n2 is an integer from 0 to 4 representing the number of Q substituents bonded to the benzene ring. In Formula (1), the proportion of the number of moles of the repeating units in which n2 is 0 is 30% or less. The proportion of the number of moles of the repeating units in which n2 is 0 is preferably from 5 to 30%. The proportion of the number of moles of the repeating units in which n2 is 1 is from 70 to 95% (the sum of the proportions of the number of moles being 100%). Q has Formula (2), (3) or (4), or a combination thereof.

In Formulas (2), (3) and (4), n3, n4 and n5 are respectively integers from 1 to 100 which represent the number of repeating units. When n1 in Formula (1) is 1, n2 is 1 or a higher integer.

The branched polyhydroxystyrene (A) has, with respect to Q, a molar ratio of repeating units of Formula (2) to repeating units of Formula (3) to repeating units of Formula (4) of 1:0.5 to 1.5:0.5 to 1.5.

The branched polyhydroxystyrene (A) may be, for example, a polymer (A-1) of the following structure.

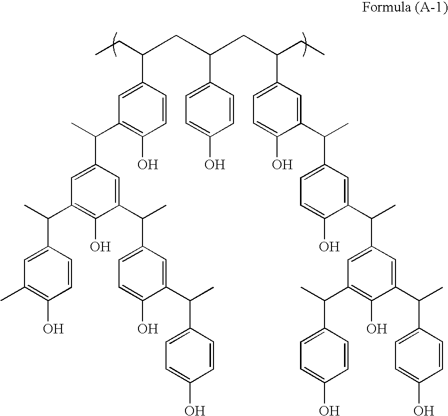

This branched polyhydroxystyrene may be acquired as, for example, the product available under the trade name BHS-B5E from DuPont Electronic Polymer K.K.

The compound having at least two vinyl ether groups used in the present invention is a compound of Formula (5).

In Formula (5), Rₐ is a divalent organic group selected from the group consisting of C₁₋₁₀ alkyl, C₆₋₄₈ aryl, C₆₋₂₅ arylalkyl, C₂₋₁₀ alkylcarbonyl, C₂₋₁₀ alkylcarbonyloxy, C₂₋₁₀ alkylcarbonylamino and C₂₋₁₀ aryloxyalkyl; R_{b} is an organic group with a valence of 2 to 4 selected from the group consisting of C₁₋₁₀ alkyl and C₆₋₁₈ aryl; and m is an integer from 2 to 4. Examples of the alkyl, aryl, arylalkyl, alkylcarbonyl, alkylcarbonyloxy, alkylcarbonylamino and aryloxyalkyl groups in Formula (5) are given below.

Illustrative examples of alkyl groups include methyl, ethyl, n-propyl, i-propyl, octyl, nonyl, cyclopropyl, n-butyl, i-butyl, s-butyl, t-butyl, cyclobutyl, 1-methylcyclopropyl, 2-methylcyclopropyl, n-pentyl, 1-methyl-n-butyl, 2-methyl-n-butyl, 3-methyl-n-butyl, 1,1-dimethyl-n-propyl, 1,2-dimethyl-n-propyl, 2,2-dimethyl-n-propyl, 1-ethyl-n-propyl, cyclopentyl, 1-methylcyclobutyl, 2-methylcyclobutyl, 3-methylcyclobutyl, 1,2-dimethylcyclopropyl, 2,3-dimethylcyclopropyl, 1-ethylcyclopropyl, 2-ethylcyclopropyl, n-hexyl, 1-methyl-n-pentyl, 2-methyl-n-pentyl, 3-methyl-n-pentyl, 4-methyl-n-pentyl, 1,1-dimethyl-n-butyl, 1,2-dimethyl-n-butyl, 1,3-dimethyl-n-butyl, 2,2-dimethyl-n-butyl, 2,3-dimethyl-n-butyl, 3,3-dimethyl-n-butyl, 1-ethyl-n-butyl, 2-ethyl-n-butyl, 1,1,2-trimethyl-n-propyl, 1,2,2-trimethyl-n-propyl, 1-ethyl-1-methyl-n-propyl, 1-ethyl-2-methyl-n-propyl, cyclohexyl, 1-methylcyclopentyl, 2-methylcyclopentyl, 3-methylcyclopentyl, 1-ethylcyclobutyl, 2-ethylcyclobutyl, 3-ethylcyclobutyl, 1,2-dimethylcyclobutyl, 1,3-dimethylcyclobutyl, 2,2-dimethylcyclobutyl, 2,3-dimethylcyclobutyl, 2,4-dimethylcyclobutyl, 3,3-dimethylcyclobutyl, 1-n-propylcyclopropyl, 2-n-propylcyclopropyl, 1-i-propylcyclopropyl, 2-i-propylcyclopropyl, 1,2,2-trimethylcyclopropyl, 1,2,3-trimethylcyclopropyl, 2,2,3-trimethylcyclopropyl, 1-ethyl-2-methylcyclopropyl, 2-ethyl-1-methylcyclopropyl, 2-ethyl-2-methylcyclopropyl and 2-ethyl-3-methylcyclopropyl. Linear alkyl groups such as methyl, ethyl and cyclohexyl are especially preferred.

Illustrative examples of aryl groups include phenyl, o-methylphenyl, m-methylphenyl, p-methylphenyl, o-chlorophenyl, m-chlorophenyl, p-chlorophenyl, o-fluorophenyl, p-fluorophenyl, o-methoxyphenyl, p-methoxyphenyl, p-nitrophenyl, p-cyanophenyl, α-naphthyl, β-naphthyl, o-biphenylyl, m-biphenylyl, p-biphenylyl, 1-anthryl, 2-anthryl, 9-anthryl, 1-phenanthryl, 2-phenanthryl, 3-phenanthryl, 4-phenanthryl and 9-phenanthryl.

Illustrative examples of arylalkyl groups include benzyl, o-methylbenzyl, m-methylbenzyl, p-methylbenzyl, o-chlorobenzyl, m-chlorobenzyl, p-chlorobenzyl, o-fluorobenzyl, p-fluorobenzyl, o-methoxybenzyl, p-methoxybenzyl, p-nitrobenzyl, p-cyanobenzyl, phenethyl, o-methylphenethyl, m-methylphenethyl, p-methylphenethyl, o-chlorophenethyl, m-chlorophenethyl, p-chlorophenethyl, o-fluorophenethyl, p-fluorophenethyl, o-methoxyphenethyl, p-methoxyphenethyl, p-nitrophenethyl, p-cyanophenethyl, 3-phenylpropyl, 4-phenylbutyl, 5-phenylpentyl, 6-phenylhexyl, α-naphthylmethyl, β-naphthylmethyl, o-biphenylylmethyl, m-biphenylylmethyl, p-biphenylylmethyl, 1-anthrylmethyl, 2-anthrylmethyl, 9-anthrylmethyl, 1-phenanthrylmethyl, 2-phenanthrylmethyl, 3-phenanthrylmethyl, 4-phenanthrylmethyl, 9-phenanthrylmethyl, α-naphthylethyl, β-naphthylethyl, o-biphenylylethyl, m-biphenylylethyl, p-biphenylylethyl, 1-anthrylethyl, 2-anthrylethyl, 9-anthrylethyl, 1-phenanthrylethyl, 2-phenanthrylethyl, 3-phenanthrylethyl, 4-phenanthrylether and 9-phenanthrylethyl.

Illustrative examples of alkylcarbonyl groups include methylcarbonyl, ethylcarbonyl, n-propylcarbonyl, i-propylcarbonyl, cyclopropylcarbonyl, n-butylcarbonyl, i-butylcarbonyl, s-butylcarbonyl, t-butylcarbonyl, cyclobutylcarbonyl, 1-methylcyclopropylcarbonyl, 2-methylcyclopropylcarbonyl, n-pentylcarbonyl, 1-methyl-n-butylcarbonyl, 2-methyl-n-butylcarbonyl, 3-methyl-n-butylcarbonyl, 1,1-dimethyl-n-propylcarbonyl, 1,2-dimethyl-n-propylcarbonyl, 2,2-dimethyl-n-propylcarbonyl, 1-ethyl-n-propylcarbonyl, cyclopentylcarbonyl, 1-methylcyclobutylcarbonyl, 2-methylcyclobutylcarbonyl, 3-methylcyclobutylcarbonyl, 1,2-dimethylcyclopropylcarbonyl, 2,3-dimethylcyclopropylcarbonyl, 1-ethylcyclopropylcarbonyl, 2-ethylcyclopropylcarbonyl, n-hexylcarbonyl, 1-methyl-n-pentylcarbonyl, 2-methyl-n-pentylcarbonyl, 3-methyl-n-pentylcarbonyl, 4-methyl-n-pentylcarbonyl, 1,1-dimethyl-n-butylcarbonyl, 1,2-dimethyl-n-butylcarbonyl, 1,3-dimethyl-n-butylcarbonyl, 2,2-dimethyl-n-butylcarbonyl, 2,3-dimethyl-n-butylcarbonyl, 3,3-dimethyl-n-butylcarbonyl, 1-ethyl-n-butylcarbonyl, 2-ethyl-n-butylcarbonyl, 1,1,2-trimethyl-n-propylcarbonyl, 1,2,2-trimethyl-n-propylcarbonyl, 1-ethyl-1-methyl-n-propylcarbonyl, 1-ethyl-2-methyl-n-propylcarbonyl, cyclohexylcarbonyl, 1-methylcyclopentylcarbonyl, 2-methylcyclopentylcarbonyl, 3-methylcyclopentylcarbonyl, 1-ethylcyclobutylcarbonyl, 2-ethylcyclobutylcarbonyl, 3-ethylcyclobutylcarbonyl, 1,2-dimethylcyclobutylcarbonyl, 1,3-dimethylcyclobutylcarbonyl, 2,2-dimethylcyclobutylcarbonyl, 2,3-dimethylcyclobutylcarbonyl, 2,4-dimethylcyclobutylcarbonyl, 3,3-dimethylcyclobutylcarbonyl, 1-n-propylcyclopropylcarbonyl, 2-n-propylcyclopropylcarbonyl, 1-i-propylcyclopropylcarbonyl, 2-i-propylcyclopropylcarbonyl, 1,2,2-trimethylcyclopropylcarbonyl, 1,2,3-trimethylcyclopropylcarbonyl, 2,2,3-trimethylcyclopropylcarbonyl, 1-ethyl-2-methylcyclopropylcarbonyl, 2-ethyl-1-methylcyclopropylcarbonyl, 2-ethyl-2-methylcyclopropylcarbonyl and 2-ethyl-3-methylcyclopropylcarbonyl.

Illustrative examples of alkylcarbonyloxy groups include methylcarbonyloxy, ethylcarbonyloxy, n-propycarbonyloxy, i-propylcarbonyloxy, cyclopropylcarbonyloxy, n-butylcarbonyloxy, i-butylcarbonyloxy, s-butylcarbonyloxy, t-butylcarbonyloxy, cyclobutylcarbonyloxy, 1-methylcyclopropylcarbonyloxy, 2-methylcyclopropylcarbonyloxy, n-pentylcarbonyloxy, 1-methyl-n-butylcarbonyloxy, 2-methyl-n-butylcarbonyloxy, 3-methyl-n-butylcarbonyloxy, 1,1-dimethyl-n-propylcarbonyloxy, 1,2-dimethyl-n-propylcarbonyloxy, 2,2-dimethyl-n-propylcarbonyloxy, 1-ethyl-n-propylcarbonyloxy, cyclopentylcarbonyloxy, 1-methylcyclobutylcarbonyloxy, 2-methylcyclobutylcarbonyloxy, 3-methylcyclobutylcarbonyloxy, 1,2-dimethylcyclopropylcarbonyloxy, 2,3-dimethylcyclopropylcarbonyloxy, 1-ethylcyclopropylcarbonyloxy, 2-ethylcyclopropylcarbonyloxy, n-hexylcarbonyloxy, 1-methyl-n-pentylcarbonyloxy, 2-methyl-n-pentylcarbonyloxy, 3-methyl-n-pentylcarbonyloxy, 4-methyl-n-pentylcarbonyloxy, 1,1-dimethyl-n-butylcarbonyloxy, 1,2-dimethyl-n-butylcarbonyloxy, 1,3-dimethyl-n-butylcarbonyloxy, 2,2-dimethyl-n-butylcarbonyloxy, 2,3-dimethyl-n-butylcarbonyloxy, 3,3-dimethyl-n-butylcarbonyloxy, 1-ethyl-n-butylcarbonyloxy, 2-ethyl-n-butylcarbonyloxy, 1,1,2-trimethyl-n-propylcarbonyloxy, 1,1,2-trimethyl-n-propylcarbonyloxy, 1-ethyl-1-methyl-n-propylcarbonyloxy, 1-ethyl-2-methyl-n-propylcarbonyloxy, cyclohexylcarbonyloxy, 1-methylcyclopentylcarbonyloxy, 2-methylcyclopentylcarbonyloxy, 3-methylcyclopentylcarbonyloxy, 1-ethylcyclobutylcarbonyloxy, 2-ethylcyclobutylcarbonyloxy, 3-ethylcyclobutylcarbonyloxy, 1,2-dimethylcyclobutylcarbonyloxy, 1,3-dimethylcyclobutylcarbonyloxy, 2,2-dimethylcyclobutylcarbonyloxy, 2,3-dimethylcyclobutylcarbonyloxy, 2,4-dimethylcyclobutylcarbonyloxy, 3,3-dimethylcyclobutylcarbonyloxy, 1-n-propylcyclopropylcarbonyloxy, 2-n-propylcyclopropylcarbonyloxy, 1-i-propylcyclopropylcarbonyloxy, 2-i-propylcyclopropylcarbonyloxy, 1,2,2-trimethylcyclopropylcarbonyloxy, 1,2,3-trimethylcyclopropylcarbonyloxy, 2,2,3-trimethylcyclopropylcarbonyloxy, 1-ethyl-2-methylcyclopropylcarbonyloxy, 2-ethyl-1-methylcyclopropylcarbonyloxy, 2-ethyl-2-methylcyclopropylcarbonyloxy and 2-ethyl-3-methylcyclopropylcarbonyloxy.

Illustrative examples of alkylcarbonylamino groups include methylcarbonylamino, ethylcarbonylamino, n-propylcarbonylamino, propylcarbonylamino, cyclopropylcarbonylamino, n-butylcarbonylamino, butylcarbonylamino, s-butylcarbonylamino, t-butylcarbonylamino, cyclobutylcarbonylamino, 1-methylcyclopropylcarbonylamino, 2-methylcyclopropylcarbonylamino, n-pentylcarbonylamino, 1-methyl-n-butylcarbonylamino, 2-methyl-n-butylcarbonylamino, 3-methyl-n-butylcarbonylamino, 1,1-dimethyl-n-propylcarbonylamino and 1,2-dimethyl-n-propylcarbonylamino.

Illustrative examples of aryloxyalkyl groups include phenyloxymethyl, o-methylphenyloxyethyl, m-methylphenyloxymethyl, p-methylphenyloxypropyl, o-chlorophenyloxymethyl, m-chlorophenyloxyethyl, p-chlorophenyloxyisopropyl, o-fluorophenyloxyethyl, p-fluorophenyloxybutoxy, o-methoxyphenyloxy-n-pentyl, p-methoxyphenyloxy-t-butyl, p-nitrophenyloxymethyl, p-cyanophenyloxy-s-butyl, α-naphthyloxymethyl, β-naphthyloxyethyl, o-biphenylyloxymethyl, m-biphenylyloxymethyl, p-biphenylyloxymethyl, 1-anthryloxymethyl, 2-anthryloxymethyl, 9-anthryloxymethyl, 1-phenanthryloxymethyl, 2-phenanthryloxymethyl, 3-phenanthryloxymethyl, 4-phenanthryloxymethyl and 9-phenanthryloxymethyl.

The compound (B) having at least two vinyl ether groups is preferably a compound having from 2 to 20, from 3 to 10, or even from 3 to 6 vinyl ether groups.

Illustrative examples of the compound (B) having at least two vinyl ether groups include bis(4-(vinyloxymethyl)cyclohexylmethyl) glutarate, tri(ethylene glycol) divinyl ether, adipic acid divinyl ester, diethylene glycol divinyl ether, tris(4-vinyloxy)butyl trimellitate, bis(4-(vinyloxy)butyl) terephthalate, bis(4-(vinyloxy)butyl isophthalate and cyclohexanedimethanol divinyl ether. These compounds may be used singly or as a combination of two or more thereof.

Use may also be made of vinyl ether compounds (B-1) of the following structure.

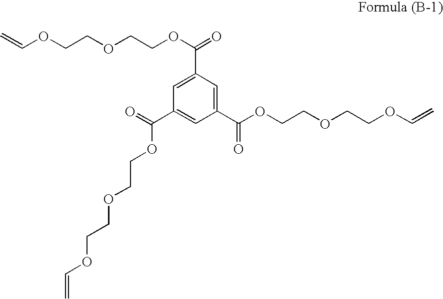

The content of the compound (B) having at least two vinyl ether groups within the resist underlayer film-forming composition solids is from 0.01 to 60 mass %, from 0.1 to 50 mass %, or even from 0.1 to 40 mass %.

The resist underlayer film-forming composition of the present invention includes a photoacid generator (C). The photoacid generator (C) is exemplified by compounds which generate an acid when irradiated with the light used in exposure. Illustrative examples of photoacid generators include diazomethane compounds, onium salt compounds, sulfonimide compounds, nitrobenzyl compounds, benzoin tosylate compounds, halogen-bearing triazine compounds and cyano group-bearing oximesulfonate compounds. Of these, onium salt compound-type photoacid generators are preferred.

Illustrative examples of onium salt compounds include iodonium salt compounds such as diphenyliodonium hexafluorophosphate, diphenyliodonium trifluoromethanesulfonate, diphenyliodonium nanofluoro-normalbutanesulfonate, diphenyliodonium perfluoro-n-octanesulfonate, diphenyliodonium camphorsulfonate, bis(4-tert-butylphenyl)iodonium camphorsulfonate and bis(4-tert-butylphenyl)iodonium trifluoromethanesulfonate, and sulfonium salt compounds such as triphenylsulfonium hexafluoroantimonate, triphenylsulfonium nanofluoro-normalbutanesulfonate, triphenylsulfonium camphorsulfonate and triphenylsulfonium trifluoromethanesulfonate.

Illustrative examples of sulfonimide compounds include N-(trifluoromethanesulfonyloxy)succinimide, N-(nanofluoro-normal butanesulfonyloxy)succinimide, N-(camphorsulfonyloxy)succinimide and N-(trifluoromethanesulfonyloxy)naphthalimide. The content of the photoacid generator (C) within the resist underlayer film-forming composition solids is from 0.01 to 15 mass %, or from 0.1 to 10 mass %. When the photoacid generator (C) is used in a content below 0.01 mass %, the proportion of acid generated becomes low, as a result of which the solubility of the exposed areas in an alkaline developer decreases, which may lead to the presence of residues following development. At a content in excess of 15 mass %, the storage stability of the resist underlayer film-forming composition may decline, as a result of which the shape of the photoresist may be affected.

The resist underlayer film-forming composition of the present invention may include a light-absorbing compound (D).

The light-absorbing compound (D) is not subject to any particular limitation, provided it is a compound having an absorption at the exposure wavelength used. Preferred use may be made of compounds having an aromatic ring structure, such as an anthracene ring, naphthalene ring, benzene ring, quinoline ring or triazine ring. Also, from the standpoint of not hindering the solubility of the resist underlayer film in an alkaline developer, a compound having a phenolic hydroxyl group, carboxyl group, hydroxyl group or sulfonic acid group is preferred.

By way of illustration, examples of light-absorbing compounds having a large absorption to light with a wavelength of 248 nm include anthracenecarboxylic acid, hydroxymethylanthracene, and 3,7-dihydroxy-2-naphthoic acid.

The light-absorbing compound (D) may be used singly or as a combination of two or more thereof. In cases where a light-absorbing compound is used, the content of this compound per 100 parts by mass of the branched polyhydroxystyrene (A) is, for example, from 1 to 300 parts by mass, from 1 to 200 parts by mass, from 3 to 100 parts by mass, or even from 5 to 50 parts by mass. When the light-absorbing compound (D) exceeds 300 parts by mass, the solubility of the resist underlayer film in an alkaline developer may decrease, or intermixing of the resist underlayer film with the photoresist may occur.

The light-absorbing compound (D) is incorporated into the crosslinked polymer by means of acetal bonds or bonds similar thereto during thermal crosslinking with the vinyl ether group-bearing compound (B). In the areas exposed to light, the crosslinkages are cleaved by the acid generated from the photoacid generator (C), resulting in the formation of hydroxyl groups and thus exhibiting solubility in an alkali developer.

Also, in cases where a light-absorbing compound (D) is used, the attenuation coefficient (k value) and refractive index (n value) of the resist underlayer film can be adjusted by varying the type and content of this compound.

The resist underlayer film-forming composition of the present invention may include an amine (E). By adding an amine, the sensitivity of the resist underlayer film during exposure can be adjusted. That is, the amine reacts with acid generated from the photoacid generator at the time of exposure, and is thus able to lower the sensitivity of the resist underlayer film. In addition, it can suppress the diffusion of acid generated from the photoacid generator (C) within the resist underlayer film in exposed areas to the resist underlayer film in unexposed areas.

Illustrative, non-limiting, examples of the amine include tertiary amines such as triethanolamine, tributanolamine, trimethylamine, triethylamine, tri-n-propylamine, tri-isopropylamine, tri-n-butylamine, tri-tert-butylamine and diazabicyclooctane; and aromatic amines such as pyridine and 4-dimethylaminopyridine. Additional examples include primary amines such as benzylamine and n-butylamine, and secondary amines such as diethylamine and di-n-butylamine.

The amine works to suppress the diffusion of acid generated by the photoacid generator (C) to the resist underlayer film in unexposed areas, and at the same time, is also incorporated into the crosslinked polymer that has been formed during thermal crosslinking from the branched polyhydroxystyrene (A) and the compound (B) having at least two vinyl ether groups. In exposed areas, the crosslinkages are then cleaved by the acid generated by the photoacid generator (C), forming hydroxyl groups which enable solubility in an alkali developer to be exhibited. An amine having hydroxyl groups is thus desirable. Preferred use can be made of triethanolamine and tributanolamine.

The amine may be used singly or as a combination of two or more types thereof. When an amine is used, the content thereof per 100 parts by mass of the branched polyhydroxystyrene (A) is, for example, from 0.001 to 5 parts by mass, from 0.01 to 1 part by mass, or even from 0.1 to 0.5 part by mass. An amine content higher than the above value may result in an excessive decline in sensitivity.

The resist underlayer film-forming composition of the present invention may include a surfactant. Illustrative examples of the surfactant include the following nonionic surfactants: polyoxyethylene alkyl ethers such as polyoxyethylene lauryl ether, polyoxyethylene stearyl ether, polyoxyethylene cetyl ether and polyoxyethylene oleyl ether; polyoxyethylene alkylaryl ethers such as polyoxyethylene octylphenol ether and polyoxyethylene nonylphenol ether; polyoxyethylene/polyoxypropylene block copolymers; sorbitan esters of fatty acids, such as sorbitan monolaurate, sorbitan monopalmitate, sorbitan monostearate, sorbitan monooleate, sorbitan trioleate and sorbitan tristearate; and polyoxyethylene sorbitan esters of fatty acids such as polyoxyethylene sorbitan monolaurate, polyoxyethylene sorbitan monopalmitate, polyoxyethylene sorbitan monostearate, polyoxyethylene sorbitan trioleate and polyoxyethylene sorbitan tristearate. Additional examples include fluorosurfactants such as Eftop EF301, EF303 and EF352 (available from Tohkem Products Co., Ltd.), Megafac F171 and F173 (Dainippon Ink and Chemicals, Inc.), Fluorad FC430 and FC431 (Sumitomo 3M Ltd.), and Asahiguard AG710 and Surflon S-382, SC101, SC102, SC103, SC104, SC105 and SC106 (Asahi Glass Co., Ltd.); and the organosiloxane polymer KP341 (Shin-Etsu Chemical Co., Ltd.). These surfactants are included in an amount, based on the overall ingredients in the resist underlayer film-forming composition of the present invention, of generally not more than 0.2 mass %, and preferably not more than 0.1 mass %. Such surfactants may be added singly or as combinations of two or more thereof.

The resist underlayer film-forming composition of the present invention may also optionally include other additives such as rheology modifiers and tackifiers.

The resist underlayer film-forming composition of the present invention may be prepared by dissolving each of the above ingredients in a suitable solvent, and is used in a uniform solution state.

Illustrative examples of such solvents include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol propyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide, N,N-dimethylacetamide and N-methylpyrrolidone. These solvents may be used singly or as combinations of two or more thereof. In addition, high-boiling solvents such as propylene glycol monobutyl ether and propylene glycol monobutyl ether acetate may be mixed and used therein.

The resist underlayer film-forming composition solution that has been prepared is preferably used following filtration with a filter having a pore size of about 0.2 μm. The resist underlayer film-forming composition solution thus prepared also has an excellent long-term storage stability at room temperature.

The use of the resist underlayer film-forming composition of the present invention is described below.

The resist underlayer film-forming composition of the present invention is coated onto a substrate (e.g., silicon/silicon dioxide-coated semiconductor substrate, silicon nitride substrate, glass substrate, ITO substrate) by a suitable coating method such as with a spinner or coater, following which a resist underlayer film is formed by baking. The baking conditions may be suitably selected from among a baking temperature of from 80 to 250° C. and a baking time of from 0.3 to 60 minutes. A baking temperature of from 130 to 250° C. and a baking time of from 0.5 to 5 minutes is preferred. Here, the thickness of the resist underlayer film may be, for example, from 0.01 to 3.0 μm, from 0.03 to 1.0 μm, or even from 0.05 to 0.5 μm.

The resist underlayer film formed from the resist underlayer film-fanning composition of the present invention is a strong film due to crosslinking of the vinyl ether compound under the baking conditions during formation. The organic solvent generally used in the photoresist solution coated thereon is one having little ability to dissolve ethylene glycol monomethyl ether, ethyl cellosolve acetate, diethylene glycol monoethyl ether, propylene glycol, propylene glycol monomethyl ether, propylene glycol monomethyl ether acetate, propylene glycol propyl ether acetate, toluene, methyl ethyl ketone, cyclohexanone, ethyl 2-hydroxypropionate, ethyl 2-hydroxy-2-methylpropionate, ethyl ethoxyacetate, methyl pyruvate, ethyl lactate and butyl lactate. For this reason, the resist underlayer film obtained from the resist underlayer film-forming composition of the present invention does not intermix with the photoresist. If the temperature during baking is lower than the above range, crosslinking will be inadequate, and intermixing with the photoresist may arise. If the baking temperature is too high, the crosslinkages will cleave, as a result of which intermixing with the photoresist may arise.

Next, a layer of photoresist is formed on the resist underlayer film. Formation of the photoresist layer may be carried out by an ordinary method, such as coating a photoresist solution onto the resist underlayer film, and baking.

The photoresist formed on the resist underlayer film of the present invention is not subject to any particular limitation, provided it is one which is sensitive to the exposure light and exhibits “positive” behavior. Examples include positive photoresists composed of a novolak resin and a 1,2-naphthoquinonediazidesulfonic acid ester; chemically amplified photoresists composed of a photoacid generator and a binder having a group that is decomposed by acid and increases the alkali dissolution rate; chemically amplified photoresists composed of a low-molecular-weight compound which is decomposed by acid and increases the alkali dissolution rate of the photoresist, an alkali-soluble binder, and a photoacid generator; and chemically amplified photoresists composed of a binder having a group that is decomposed by acid and increases the alkali dissolution rate, a low-molecular-weight compound which is decomposed by acid and increases the alkali dissolution rate, and a photoacid generator. Illustrative examples include that available under the trade name APEX-E from the Shipley Company, L.L.C., that available under the trade name PAR 710 from Sumitomo Chemical Co., Ltd., and that available under the trade name SEPR 430 from Shin-Etsu Chemical Co., Ltd.

Semiconductor devices are manufactured by a process which includes the steps of: forming a resist underlayer film by coating, then baking, the resist underlayer film-forming composition on the semiconductor substrate; forming a photoresist layer on the resist underlayer film; exposing the semiconductor substrate covered with the resist underlayer film and the photoresist layer to light through a photomask; and carrying out development following exposure.

Exposure is carried out through a predetermined mask. A KrF excimer laser (wavelength, 248 nm), ArF excimer laser (wavelength, 193 nm) or F2 excimer laser (wavelength, 157 nm) may be used for exposure. Following exposure, if necessary, post-exposure bake is carried out. The post-exposure bake conditions are suitably selected from a heating temperature of 80 to 150° C. and a heating time of 0.3 to 60 minutes.

The semiconductor device is manufactured by a step that involves exposure, through a photomask, of the semiconductor substrate covered with the resist underlayer film and the photoresist layer, followed by development.

The resist underlayer film formed from the resist underlayer film-forming composition of the present invention, owing to the action of the acid generated by the photoacid generator within the resist underlayer film during exposure, is soluble, together with the photoresist, within the alkaline developer used during development.

When the combined development of the two layers with the developer is carried out following exposure, the exposed areas of both the photoresist layer and the resist underlayer film exhibit alkali solubility.

Next, development is carried out with an alkaline developer, thereby removing the photoresist in the exposed areas and the resist underlayer film in the underlying areas.

The alkaline developer is exemplified by the following aqueous alkaline solutions: aqueous solutions of an alkaline metal hydroxide such as potassium hydroxide or sodium hydroxide; aqueous solutions of a quaternary ammonium hydroxide such as tetramethylammonium hydroxide, tetraethylammonium hydroxide or choline; and aqueous solutions of an amine such as ethanolamine, propylamine and ethylenediamine. A surfactant may be added to these developers.

The development conditions are suitably selected from a temperature of from 5 to 50° C. and a time of from 10 to 300 seconds. The resist underlayer film formed from the resist underlayer film-forming composition of the present invention can easily be developed at room temperature using a 2.38 mass % tetramethylammonium hydroxide solution in water commonly used for photoresist development.

The resist underlayer film of the present invention may also be used as, for example, a layer for preventing interaction between the substrate and the photoresist, a layer having the function of preventing adverse effects on the semiconductor substrate by materials used in the photoresist or materials that form upon exposure of the photoresist to light, a layer having the function of preventing materials that arise from the semiconductor substrate during heating and baking from diffusing to the overlying photoresist, and a layer for reducing photoresist poisoning effects by the dielectric layer on the semiconductor substrate.

Resist underlayer films obtained from resist underlayer film-forming compositions of the present invention are illustrated specifically in the following examples, although the present invention is not limited by these examples.

### EXAMPLES

### Synthesis of Light-Absorbing Compounds

### Synthesis Example 1

Solution [D-1] containing the light-absorbing compound of Formula (D-1) below was obtained by adding 38.0 g of 3,7-dihydroxy-2-naphthoic acid, 20 g of tris(2,3-epoxypropyl) isocyanurate and 1.104 g of benzyltriethylammonium chloride to 136 g of cyclohexanone, and subjecting them to reaction at 130° C. for 24 hours.

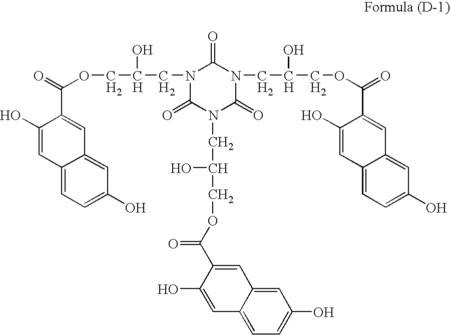

### Synthesis Example 2

Solution [D-2] containing the light-absorbing compound of Formula (D-2) below was obtained by adding 17.3 g of 3,7-dihydroxy-2-naphthoic acid, 37.5 g of 9-anthracenecarboxylic acid, 25 g of tris(2,3-epoxypropyl) isocyanurate and 1.5 g of benzyltriethylammonium chloride to 405 g of cyclohexanone, and subjecting them to reaction at 130° C. for 24 hours.

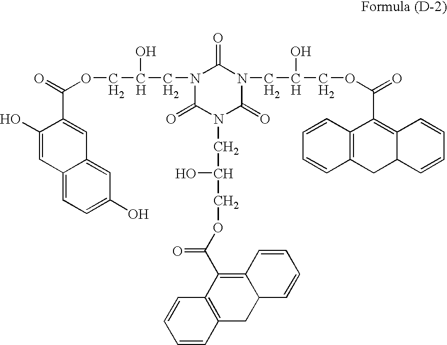

### Synthesis Example 3

Solution [D-3] containing the light-absorbing compound of Formula (D-3) below was obtained by adding 30 g of 9-anthracenecarboxylic acid, 26.2 g of pamoic acid, 20 g of tris(2,3-epoxypropyl) isocyanurate and 1.2 g of benzyltriethylammonium chloride to 386 g of cyclohexanone, and subjecting them to reaction at 130° C. for 24 hours.

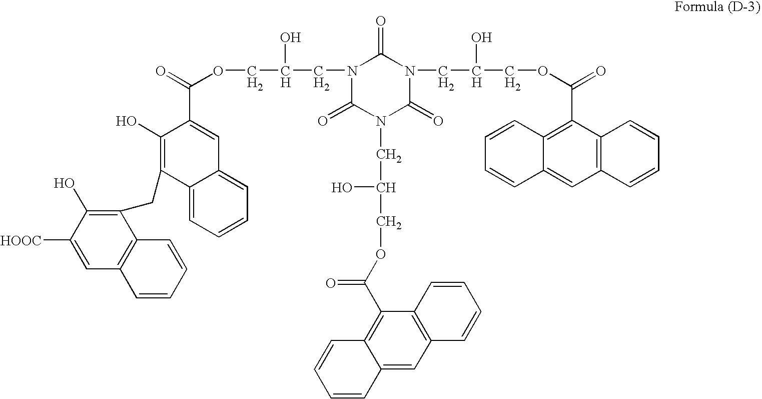

### Compounds Having at Least Two Vinyl Ether Groups

1,3,5-Tris(4-vinyloxy)butyl trimellitate having Formula (B-1),

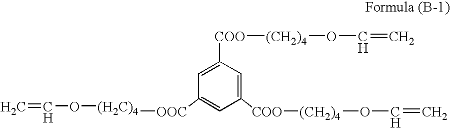

and 1,2,4-tris(4-vinyloxy)butyl trimellitate having Formula (B-2)

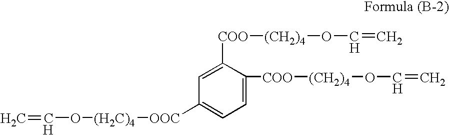

were furnished as compounds having at least two vinyl ether groups.

### Photoacid Generators

Triphenylsulfonium trifluoromethanesulfonate having Formula (C-1),

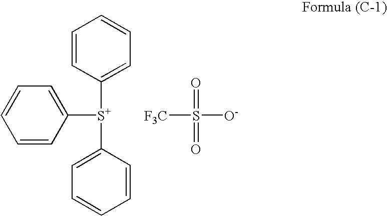

and triphenylsulfonium nonafluorobutanesulfonate having Formula (C-2)

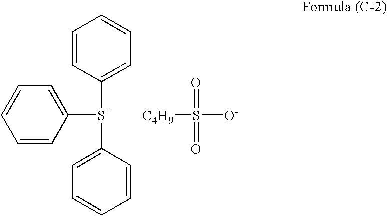

were furnished as photoacid generators.

### Example 1

### Preparation of Resist Underlayer Film-Forming Composition (Anti-Reflective Coating-Forming Composition)

A Solution [1] of a resist underlayer film-forming composition was prepared by adding 5 g of the above alkali-soluble resin (A-1) (trade name PHS-B5E; molecular weight, about 5,000), 3.25 g of 1,3,5-tris(4-vinyloxy)butyl trimellitate (B-1), 18.2 g of a light-absorbing compound (D-1), 0.29 g of triphenylsulfonium trifluoromethanesulfonate (C-1) and 0.04 g of triethanolamine (E) to 21.6 g of propylene glycol monomethyl ether and 406 g of propylene glycol monomethyl ether acetate, then stirring for 30 minutes at room temperature.

### Evaluation of Resist Underlayer Film-Forming Composition (Anti-Reflective Coating-Forming Composition)

This Solution [1] of a resist underlayer film-forming composition was coated onto a semiconductor substrate (silicon wafer) using a spinner, then baked on a hot plate at a temperature of 180° C. for 60 seconds, thereby forming a resist underlayer film having a thickness of 46 nm. The resulting resist underlayer film was insoluble in ethyl lactate, propylene glycol monomethyl ether, propylene glycol monomethyl ether acetate, and a 2.38 mass % tetramethylammonium hydroxide solution in water (available from Tokyo Ohka Kogyo Co., Ltd. under the trade name NMD-3). Measurement of this resist underlayer film with a spectroscopic ellipsometer revealed that the film had a reflectance (n value) of 1.51 and an attenuation coefficient (k value) of 0.48 at a wavelength of 193 nm, and had a reflectance (n value) of 1.82 and an attenuation coefficient (k value) of 0.31 at a wavelength of 248 nm.

The Solution [1] of a resist underlayer film-forming composition was coated onto a silicon wafer using a spinner, then baked on a hot plate at a temperature of 180° C. for 60 seconds, thereby forming a resist underlayer film having a thickness of 46 nm. A KrF positive photoresist was formed on the resulting resist underlayer film, and exposed with a KrF excimer laser (wavelength, 248 nm) through a mask. After 90 seconds of exposure at a temperature of 110° C. followed by heating, 60 seconds of paddle development was carried out using a 2.38 mass % tetramethylammonium hydroxide solution in water (available from Tokyo Ohka Kogyo Co., Ltd. under the trade name NMD-3) as the alkaline developer. Both the photoresist and the resist underlayer film dissolved in the exposed areas; no remnants of either were observed.

### Example 2

### Preparation of Resist Underlayer Film-Forming Composition (Anti-Reflective Coating-Forming Composition)

A Solution [2] of a resist underlayer film-forming composition was prepared by adding 3 g of the above alkali-soluble resin (A-1) (trade name PHS-B5E), 1.95 g of 1,3,5-tris(4-vinyloxy)butyl trimellitate (B-1), 25.9 g of a light-absorbing compound (D-2), 0.17 g of triphenylsulfonium trifluoromethanesulfonate (C-1) and 0.03 g of triethanolamine (E) to 12.9 g of propylene glycol monomethyl ether and 245 g of propylene glycol monomethyl ether acetate, then stirring for 30 minutes at room temperature.

### Evaluation of Resist Underlayer Film-Forming Composition (Anti-Reflective Coating-Forming Composition)

This Solution [2] of a resist underlayer film-forming composition was coated onto a semiconductor substrate (silicon wafer) using a spinner, then baked on a hot plate at a temperature of 180° C. for 60 seconds, thereby forming a resist underlayer film having a thickness of 52 nm. The resulting resist underlayer film was insoluble in ethyl lactate, propylene glycol monomethyl ether, propylene glycol monomethyl ether acetate, and a 2.38 mass % tetramethylammonium hydroxide solution in water (available from Tokyo Ohka Kogyo Co., Ltd. under the trade name NMD-3). Measurement of this resist underlayer film with a spectroscopic ellipsometer revealed that the film had a reflectance (n value) of 1.52 and an attenuation coefficient (k value) of 0.48 at a wavelength of 193 nm, and a reflectance (n value) of 1.69 and an attenuation coefficient (k value) of 0.39 at a wavelength of 248 nm.

The Solution [2] of a resist underlayer film-forming composition was coated onto a silicon wafer using a spinner, then baked on a hot plate at a temperature of 180° C. for 60 seconds, thereby forming a resist underlayer film having a thickness of 52 nm. A KrF positive photoresist was formed on the resulting resist underlayer film, and exposed with a KrF excimer laser (wavelength, 248 nm) through a mask. After 90 seconds of exposure at a temperature of 110° C. followed by heating, 60 seconds of paddle development was carried out using a 2.38 mass % tetramethylammonium hydroxide solution in water (available from Tokyo Ohka Kogyo Co., Ltd. under the trade name NMD-3) as the alkaline developer. Both the photoresist and the resist underlayer film dissolved in the exposed areas; no remnants of either were observed.

### Example 3

### Preparation of Resist Underlayer Film-Forming Composition (Anti-Reflective Coating-Forming Composition)

A Solution [3] of a resist underlayer film-forming composition was prepared by adding 4 g of the above alkali-soluble resin (A-1) (trade name PHS-B5E), 2.6 g of 1,3,5-tris(4-vinyloxy)butyl trimellitate (B-1), 32.5 g of a light-absorbing compound (D-3), 0.23 g of triphenylsulfonium trifluoromethanesulfonate (C-1) and 0.03 g of triethanolamine (E) to 17.2 g of propylene glycol monomethyl ether and 328 g of propylene glycol monomethyl ether acetate, then stirring for 30 minutes at room temperature.

### Evaluation of Resist Underlayer Film-Forming Composition (Anti-Reflective Coating-Forming Composition)

This Solution [3] of a resist underlayer film-forming composition was coated onto a semiconductor substrate (silicon wafer) using a spinner, then baked on a hot plate at a temperature of 180° C. for 60 seconds, thereby forming a resist underlayer film having a thickness of 51 nm. The resulting resist underlayer film was insoluble in ethyl lactate, propylene glycol monomethyl ether, propylene glycol monomethyl ether acetate, and a 2.38 mass % tetramethylammonium hydroxide solution in water (available from Tokyo Ohka Kogyo Co., Ltd. under the trade name NMD-3). Measurement of this resist underlayer film with a spectroscopic ellipsometer revealed that the film had a reflectance (n value) of 1.52 and an attenuation coefficient (k value) of 0.50 at a wavelength of 193 nm, and a reflectance (n value) of 1.75 and an attenuation coefficient (k value) of 0.29 at a wavelength of 248 nm.

The Solution [3] of a resist underlayer film-forming composition solution was coated onto a silicon wafer using a spinner, then baked on a hot plate at a temperature of 180° C. for 60 seconds, thereby forming a resist underlayer film having a thickness of 51 nm. A KrF positive photoresist was formed on the resulting resist underlayer film, and exposed with a KrF excimer laser (wavelength, 248 nm) through a mask. After 90 seconds of exposure at a temperature of 110° C. followed by heating, 60 seconds of paddle development was carried out using a 2.38 mass % tetramethylammonium hydroxide solution in water (available from Tokyo Ohka Kogyo Co., Ltd. under the trade name NMD-3) as the alkaline developer. Both the photoresist and the resist underlayer film dissolved in the exposed areas; no remnants of either were observed.

### Example 4

Aside from changing the 1,3,5-tris(4-vinyloxy)butyl trimellitate (B-1) used in Solution [1] of a resist underlayer film-forming composition in Example 1 to 1,2,4-tris(4-vinyloxy)butyl trimellitate (B-2), a Solution [4] of a resist underlayer film-forming composition was prepared in the same manner as in Example 1. Solution [4] was coated onto a semiconductor substrate (silicon wafer) using a spinner, then baked on a hot plate at a temperature of 180° C. for 60 seconds, thereby fowling a resist underlayer film. A KrF positive photoresist was formed on the resulting resist underlayer film, and exposed with a KrF excimer laser (wavelength, 248 nm) through a mask. After 90 seconds of exposure at a temperature of 110° C. followed by heating, 60 seconds of paddle development was carried out using a 2.38 mass tetramethylammonium hydroxide solution in water (available from Tokyo Ohka Kogyo Co., Ltd. under the trade name NMD-3) as the alkaline developer. Both the photoresist and the resist underlayer film dissolved in the exposed areas; no remnants of either were observed.

### Example 5

Aside from changing the 1,3,5-tris(4-vinyloxy)butyl trimellitate (B-1) used in Solution [2] of a resist underlayer film-forming composition in Example 2 to 1,2,4-tris(4-vinyloxy)butyl trimellitate (B-2), a Solution [5] of a resist underlayer film-forming composition was prepared in the same manner as in Example 1. Solution [5] was coated onto a semiconductor substrate (silicon wafer) using a spinner, then baked on a hot plate at a temperature of 180° C. for 60 seconds, thereby forming a resist underlayer film. A KrF positive photoresist was formed on the resulting resist underlayer film, and exposed with a KrF excimer laser (wavelength, 248 nm) through a mask. After 90 seconds of exposure at a temperature of 110° C. followed by heating, 60 seconds of paddle development was carried out using a 2.38 mass % tetramethylammonium hydroxide solution in water (available from Tokyo Ohka Kogyo Co., Ltd. under the trade name NMD-3) as the alkaline developer. Both the photoresist and the resist underlayer film dissolved in the exposed areas; no remnants of either were observed.

### Example 6

Aside from changing the 1,3,5-tris(4-vinyloxy)butyl trimellitate (B-1) used in Solution [3] of a resist underlayer film-forming composition in Example 3 to 1,2,4-tris(4-vinyloxy)butyl trimellitate (B-2), a Solution [6] of a resist underlayer film-forming composition was prepared in the same manner as in Example 1. Solution [6] was coated onto a semiconductor substrate (silicon wafer) using a spinner, then baked on a hot plate at a temperature of 180° C. for 60 seconds, thereby forming a resist underlayer film. A KrF positive photoresist was formed on the resulting resist underlayer film, and exposed with a KrF excimer laser (wavelength, 248 nm) through a mask. After 90 seconds of exposure at a temperature of 110° C. followed by heating, 60 seconds of paddle development was carried out using a 2.38 mass % tetramethylammonium hydroxide solution in water (available from Tokyo Ohka Kogyo Co., Ltd. under the trade name NMD-3) as the alkaline developer. Both the photoresist and the resist underlayer film dissolved in the exposed areas; no remnants of either were observed.

### Example 7

Aside from changing the triphenylsulfonium trifluoromethanesulfonate (C-1) (B-1) used in Solution [1] of a resist underlayer film-forming composition in Example 1 to triphenylsulfonium nonafluorobutanesulfonate (C-2), a Solution [7] of a resist underlayer film-forming composition was prepared in the same manner as in Example 1. Solution [7] was coated onto a semiconductor substrate (silicon wafer) using a spinner, then baked on a hot plate at a temperature of 180° C. for 60 seconds, thereby forming a resist underlayer film. A KrF positive photoresist was formed on the resulting resist underlayer film, and exposed with a KrF excimer laser (wavelength, 248 nm) through a mask. After 90 seconds of exposure at a temperature of 110° C. followed by heating, 60 seconds of paddle development was carried out using a 2.38 mass % tetramethylammonium hydroxide solution in water (available from Tokyo Ohka Kogyo Co., Ltd. under the trade name NMD-3) as the alkaline developer. Both the photoresist and the resist underlayer film dissolved in the exposed areas; no remnants of either were observed.

### Example 8

Aside from changing the triphenylsulfonium trifluoromethanesulfonate (C-1) used in Solution [2] of a resist underlayer film-forming composition in Example 2 to triphenylsulfonium nonafluorobutanesulfonate (C-2), a Solution [8] of a resist underlayer film-forming composition was prepared in the same manner as in Example 1. Solution [8] was coated onto a semiconductor substrate (silicon wafer) using a spinner, then baked on a hot plate at a temperature of 180° C. for 60 seconds, thereby forming a resist underlayer film. A KrF positive photoresist was formed on the resulting resist underlayer film, and exposed with a KrF excimer laser (wavelength, 248 nm) through a mask. After 90 seconds of exposure at a temperature of 110° C. followed by heating, 60 seconds of paddle development was carried out using a 2.38 mass % tetramethylammonium hydroxide solution in water (available from Tokyo Ohka Kogyo Co., Ltd. under the trade name NMD-3) as the alkaline developer. Both the photoresist and the resist underlayer film dissolved in the exposed areas; no remnants of either were observed.

### Example 9

Aside from changing the triphenylsulfonium trifluoromethanesulfonate (C-1) used in Solution [3] of a resist underlayer film-forming composition in Example 3 to triphenylsulfonium nonafluorobutanesulfonate (C-2), a Solution [9] of a resist underlayer film-forming composition was prepared in the same manner as in Example 1. Solution [9] was coated onto a semiconductor substrate (silicon wafer) using a spinner, then baked on a hot plate at a temperature of 180° C. for 60 seconds, thereby forming a resist underlayer film. A KrF positive photoresist was formed on the resulting resist underlayer film, and exposed with a KrF excimer laser (wavelength, 248 nm) through a mask. After 90 seconds of exposure at a temperature of 110° C. followed by heating, 60 seconds of paddle development was carried out using a 2.38 mass % tetramethylammonium hydroxide solution in water (available from Tokyo Ohka Kogyo Co., Ltd. under the trade name NMD-3) as the alkaline developer. Both the photoresist and the resist underlayer film dissolved in the exposed areas; no remnants of either were observed.

### Comparative Example 1

### Preparation of Resist Underlayer Film-Forming Composition (Anti-Reflective Coating-Forming Composition)

A solution [10] of a resist underlayer film-forming composition was prepared by adding 5 g of a linear poly(p-hydroxystyrene) (available from Nippon Soda Co., Ltd. under the trade name VP-8000) having substantially the same molecular weight as the above alkali-soluble resin PHS-B5E (A-1), 3.25 g of 1,3,5-tris(4-vinyloxy)butyl trimellitate (B-1), 18.2 g of a light-absorbing compound (D-1), 0.29 g of triphenylsulfonium trifluoromethanesulfonate (C-1) and 0.04 g of triethanolamine (E) to 21.6 g of propylene glycol monomethyl ether and 406 g of propylene glycol monomethyl ether acetate, then stirring for 30 minutes at room temperature.

### Evaluation of Resist Underlayer Film-Forming Composition (Anti-Reflective Coating-Forming Composition)

This Solution [10] of a resist underlayer film-forming composition was coated onto a semiconductor substrate (silicon wafer) using a spinner, then baked on a hot plate at a temperature of 180° C. for 60 seconds, thereby forming a resist underlayer film having a thickness of 46 nm. Of the resulting resist underlayer film, 7.5 nm dissolved in ethyl lactate, propylene glycol monomethyl ether, and propylene glycol monomethyl ether acetate. That is, because the crosslinkablity was lower than in cases where a branched polyhydroxystyrene was used, the solvent resistance was low. The resist underlayer film was insoluble in a 2.38 mass % tetramethylammonium hydroxide solution in water (available from Tokyo Ohka Kogyo Co., Ltd. under the trade name NMD-3). Measurement of this resist underlayer film with a spectroscopic ellipsometer revealed that the film had a reflectance (n value) of 1.57 and an attenuation coefficient (k value) of 0.62 at a wavelength of 193 nm; and a reflectance (n value) of 1.78 and an attenuation coefficient (k value) of 0.28 at a wavelength of 248 nm.

The Solution [10] of a resist underlayer film-forming composition was coated onto a silicon wafer using a spinner, then baked on a hot plate at a temperature of 180° C. for 60 seconds, thereby forming a resist underlayer film having a thickness of 46 nm. A KrF positive photoresist was formed on the resulting resist underlayer film, and exposed with a KrF excimer laser (wavelength, 248 nm) through a mask. After 90 seconds of exposure at a temperature of 110° C. followed by heating, 60 seconds of paddle development was carried out using a 2.38 mass % tetramethylammonium hydroxide solution in (available from Tokyo Ohka Kogyo Co., Ltd. under the trade name NMD-3) as the alkaline developer. Both the photoresist and the resist underlayer film dissolved in the exposed areas; no remnants of either were observed. However, compared with the resist underlayer film formed from Solution [1] of a resist underlayer film-forming composition, a 1.5 times higher exposure dose was required until remnants of the films ceased to be observable.

From the above results, with resist underlayer films formed from Solutions [1] to [9] of resist underlayer film-forming compositions according to the present invention, because a branched polyhydroxystyrene (A) is used as the resin, thermal crosslinkages with the vinyl ether group-bearing compound (B), the light-absorbing compound (D), etc., form in many places. Moreover, the places where these thermal crosslinkages have formed are also places that are cleaved by the acid generated by the photoacid generator at the time of exposure and exhibit solubility in an aqueous alkali solution. Therefore, in cases where a branched polyhydroxystyrene is used as the resin, when thermally crosslinked, the branched polyhydroxystyrene has a sufficient solvent resistance to the resist coated thereon and also has a high aqueous alkali solution solubility due to the acid generated during exposure.

By contrast, in the resist underlayer film formed from Solution [10] of a resist underlayer film-forming composition in the comparative example, because a linear polyhydroxystyrene is used as the resin, even though the equivalence of phenolic hydroxyl groups per unit weight is the same, the above-described effects are not achieved.

The reason is thought to be that the branched polyhydroxystyrene has a higher density of phenolic hydroxyl groups per unit volume than the linear polyhydroxystyrene.

By making use of such characteristics, a resist underlayer film that employs a branched polyhydroxystyrene as the resin can be advantageously employed in a lithographic wet etching process for semiconductor devices.

1. A resist underlayer film-forming composition for use in a lithographic process for manufacturing a semiconductor device, containing:
(A) a branched polyhydroxystyrene in which an ethylene repeating unit on a polyhydroxystyrene moiety is bonded to a benzene ring on a different polyhydroxystyrene moiety;
(B) a compound having at least two vinyl ether groups; and
(C) a photoacid generator.

2. The resist underlay film-forming composition according to claim 1, wherein the branched polyhydroxystyrene (A) includes a structure of Formula (1) 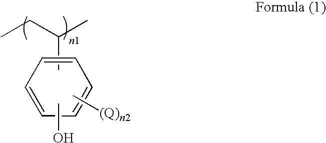
[where Q is a polyhydroxystyrene moiety bonded to a benzene ring, n1 is a number from 1 to 100 representing the number of ethylene repeating units, n2 is an integer from 0 to 4 representing the number of Q substituents bonded to the benzene ring, and Q has Formula (2), (3) or (4) 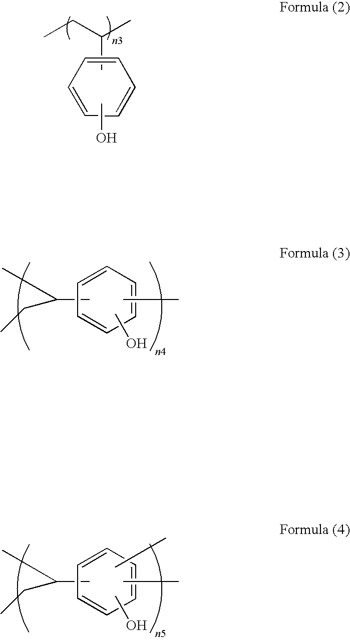
(where n3, n4 and n5 are respectively integers from 1 to 100 which represent the number of repeating units), or is a combination thereof] and has a weight average molecular weight of from 1,000 to 100,000.

3. The resist underlayer film-forming composition according to claim 2, wherein the branched polyhydroxystyrene (A) has a proportion of the number of moles of repeating units of Formula (1), in which n2 in the formula is 0, ranging from 5 to 30% and a proportion of the number of moles of repeating units of Formula (1), in which n2 in the formula is 1, ranging from 70 to 95% (the sum of the proportions of the number of moles being 100%), and has, with respect to Q, a molar ratio of repeating units of Formula (2) to repeating units of Formula (3) to repeating units of Formula (4) of 1:0.5 to 1.5:0.5 to 1.5.

4. The resist underlayer film-forming composition according to claim 1, wherein the compound (B) having at least two vinyl ether groups is a compound of Formula (5) 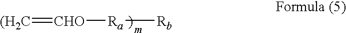
(where Rₐ is a divalent organic group selected from the group consisting of C₁₋₁₀ alkyl, C₆₋₁₈ aryl, C₆₋₂₅ arylalkyl, C₂₋₁₀ alkylcarbonyl, C₂₋₁₀ alkylcarbonyloxy, C₂₋₁₀ alkylcarbonylamino and C₂₋₁₀ aryloxyalkyl; R_{b} is an organic group with a valence of 2 to 4 selected from the group consisting of C₁₋₁₀ alkyl and C₆₋₁₈ aryl; and m is an integer from 2 to 4).

5. The resist underlayer film-forming composition according to claim 1, further comprising (D) a light-absorbing compound.

6. The resist underlayer film-forming composition according to claim 1, further comprising (E) an amine.

7. A method for forming photoresist pattern for use in semiconductor manufacture, comprising the step of forming a resist underlayer film by coating the resist underlayer film-forming composition according to claim 1 onto a semiconductor substrate and baking the coated composition.

8. A method for manufacturing semiconductor device comprising the steps of:
forming a resist underlayer film on a semiconductor substrate using the resist underlayer film-forming composition according to claim 1;
forming a resist film on the resist underlayer film; and
forming a resist pattern by exposure and development.

9. The semiconductor device manufacturing process according to claim 8, wherein areas that have been exposed exhibit alkali solubility and are removed in use of a developer to form a resist pattern.
